(19) United States
(12) Patent Application Publication
(10) Pub. No.: US 2002/0143482 A1
(43) Pub. Date: Oct. 3, 2002

(54) Method and apparatus for monitoring electrical usage

(76) Inventors: Rajaiah Karanam, Bristol, CT (US); Khalil Ebrahim Shaikh, Farmington, CT (US); Henry George, Farmington, CT (US); Ronald Jerdonek, West Hartford, CT (US); Hawkins Cui, Middletown, CT (US)

Correspondence Address: PATENT OPERATION, GENERAL ELECTRIC COMPANY, 41 WOODFORD AVENUE, PLAINVILLE, CT, 06062

(21) Appl. No.: 09/681,425

(22) Filed: Mar. 30, 2001

(51) Int. Cl. G01R 21/06; G06F 19/00

(52) U.S. Cl. 702/62

(57) ABSTRACT

A system for monitoring electricity usage is provided. The system includes a monitoring device having a meter connected to a current transformer and a communications device. The communications device allows transmission of electrical usage information to a server. The data is communicated to the server where it is stored and analyzed to create reports such as demand profile and billing verification.

### FIELD OF THE INVENTION

The present invention relates generally to a system for monitoring electrical usage. More particularly to a system which collects electricity usage information and transmits the information to a central location for analysis.

### BACKGROUND OF INVENTION

This invention relates generally to electrical distribution systems and more particularly to a computer-based method and system for installing sub-metering equipments and analyzing energy data.

Energy auditing is a primary method of collecting and analyzing electrical usage data for electricity utility savings. However, an energy auditing system consists the following components and services: current transformers, electrical meters, wires, computer software, communication devices, a computer, installation and dedicated monitoring personnel. Many existing electrical distribution systems without energy auditing environment are not designed for easily retrofitting such system.

Therefore, it would be desirable and economical to provide an electricity utility user with an energy auditing retrofit bundle which contains complete hardware, material, computer software user interface, installation instruction and an optional computer.

### SUMMARY OF INVENTION

In an exemplary embodiment of the present invention, a system for monitoring electricity usage is provided. The system includes a monitoring device having a meter connected to a current transformer and a communications device. The communications device allows transmission of electrical usage information to a server. The data is communicated to the server where it is stored and analyzed to create reports such as demand profile and billing verification. In an alternate embodiment, the server also uses the electrical usage information to determine a new demand profile that results in lower electrical costs for the facility.

Additional objects, advantages and novel features of the invention will be set forth in part in the description which follows, and in part will become apparent to those skilled in the art upon examination of the following or may be learned by practice of the invention. The objects and advantages of the invention may be realized and attained by means of instrumentalities and combinations particularly pointed out in the appended claims.

### BRIEF DESCRIPTION OF DRAWINGS

FIG. 1 is a perspective view illustrating a facility using a retrofitable power monitoring system;

FIG. 2 is a front view of a monitoring device used in the system of FIG. 1;

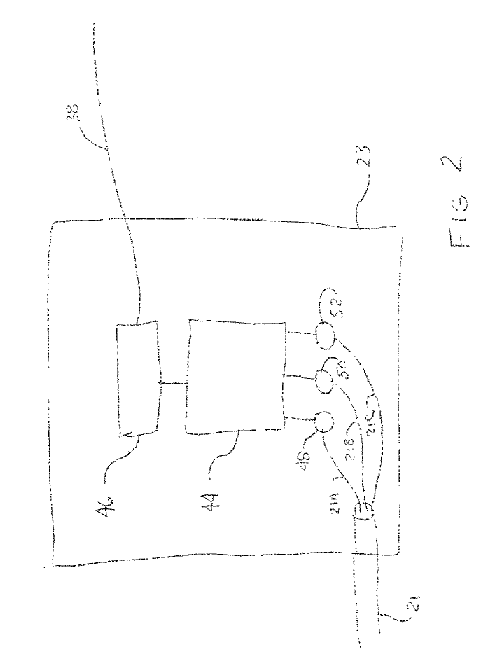

FIG. 3 is a demand graph report generated by the system of FIG. 1;

FIG. 4 is a demand statistics report generated by the system of FIG. 1;

FIG. 5 is a bill verification report generated by the system of FIG. 1;

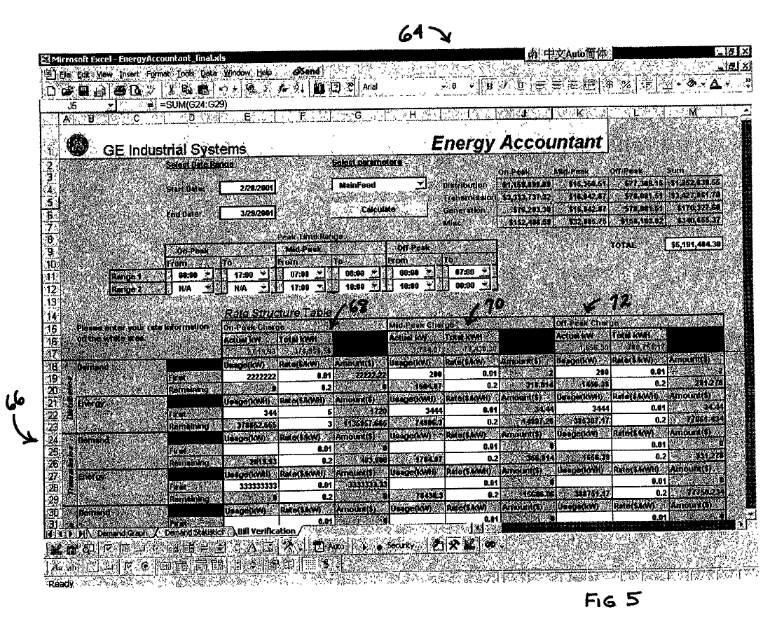

FIG. 6 is a flowchart describing the process of determining a new demand profile.

### DETAILED DESCRIPTION

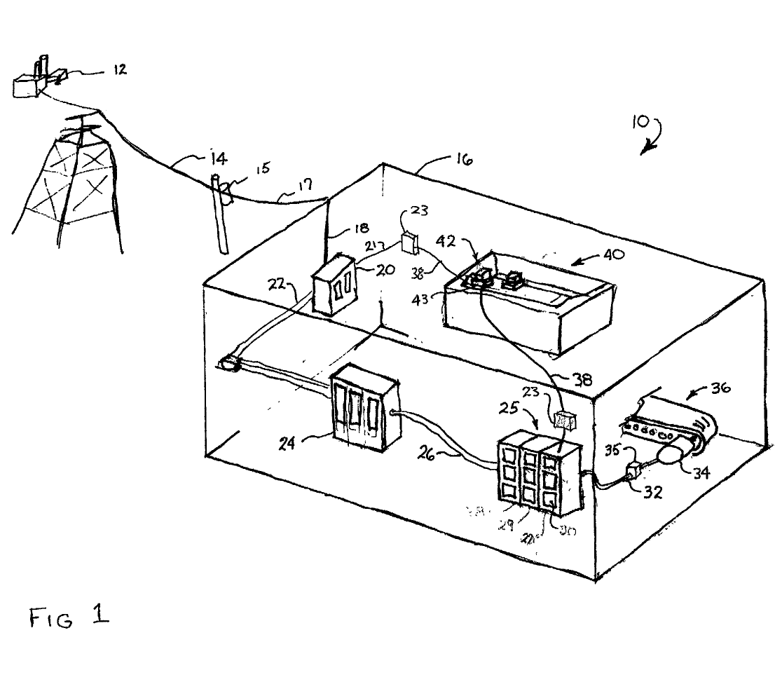

Industrial manufacturing facilities such as those that manufacture goods, or process materials, often utilize complex electrical distribution systems in their operations. Such a distribution system 10 is shown in FIG. 1, the electrical power needed by the industrial facility is generated at a power generation plant 12. High voltage electricity is delivered via transmission and distribution grid 14. The system also includes one or more transformers 15 which step down the high voltage electricity to lower voltages that can be used by the manufacturing facility 16. After the last transformer 15, a low voltage line 17 delivers the electricity to the service entrance 18 of the manufacturing facility 16. Usually, in medium to large facilities, three-phase electrical power is delivered for use. In light manufacturing and residential applications only a single phase of electrical power may be delivered.

Typically, a circuit breaker 20 will be located at the service entrance 18. The circuit breaker may be any suitable industrial circuit breaker such as an air circuit breaker mounted in switchgear. The service entrance circuit breaker 20 serves as a switch for disconnecting the facility 16 from the electrical distribution grid 14.

A busway or cable 22 exits the service entrance circuit breaker 20 and delivers the electrical power to the various distribution subsystems within the facility. Usually these system include one or more panelboards 24 which contain banks of circuit breakers (not shown) that divide the electrical power into a number of circuits. The circuit breakers in the panelboards isolate the individual circuits, allowing for example, a circuit on one machine to be disconnected without effecting the remainder of the building.

As will be described in more detail herein, a monitoring device 23 is also connected to the service entrance circuit breaker 20. The monitoring device 23 collects information on electrical usage for the building. in the preferred embodiment, the monitoring device is connected to a power management and control system 42.

In manufacturing facilities utilizing large industrial motors, at least one of the circuits 26 will deliver electrical power to a motor control center 25. As will be described in more detail herein, the motor control center 25 has a plurality of sections. These sections contain a number of individual units which further divide the electrical power into further circuits and are used to control and monitor the performance of the industrial motor 34 associated with a particular circuit. After exiting the motor control center unit 30, the electrical power is delivered by a cable or busway 32 to a local control device 35 which further refines the control or performance of the industrial motor 34. The local control device 35 could for example, be as simple as a contactor, or a more complex device such as motor soft starter. The industrial motor 34 drives a manufacturing process 36 such as a conveyor or a mixer.

Manufacturing operations consume large amounts of electrical power. To reduce costs and gain more efficiency out of their facilty, a power management and control system 42 may be used. To monitor the operation of the facility, the monitoring system 42 includes a server 43 preferably located in a central control room 40. By server it understood that this could include a traditional server such as a desktop computer, or may be a handheld personal digital assistance that receives the data through any communications source (e.g. wirelessly) as described hereafter.

From the control room 40, communications wiring 38 connects the monitoring system with various monitoring devices 23 throughout the facility 16. The monitoring devices 23 are located in areas where detailed information on the electrical usage is desired. Typical locations would include near the service entrance 20 and the motor control center 25.

The three phase electrical power is brought to the the monitoring device 23 by a cable 21. Each electrical phase of the cable 21A, 21B, 21C is connected with a current transformer 48, 50 ,52 respectively. In the preferred embodiment, the transformer is a split type transformer that allows the current transformer to be installed as part of a retrofit installation addition the monitoring system without disrupting the electrical service to the facilty. The current transformers provide a signal indicative the magnitude of electrical current to a meter 44. The meter receives the signal and calculates various electrical usage parameters such as demand and maximum current. These parameters are stored and periodically transmitted by a communications device 46, such as a RS232-485 converter. The signal is transmitted over communications wiring 38 to the server 43 in the central control room 40. While the communications link is shown here as a wire 38, this communication can take place over any suitable medium, such as infrared, radio, cellular telephone. The communications may also take Ethernet network or the internet. It should be noted that while the communications device 46 is shown as a separate device, it may also be integral with the meter.

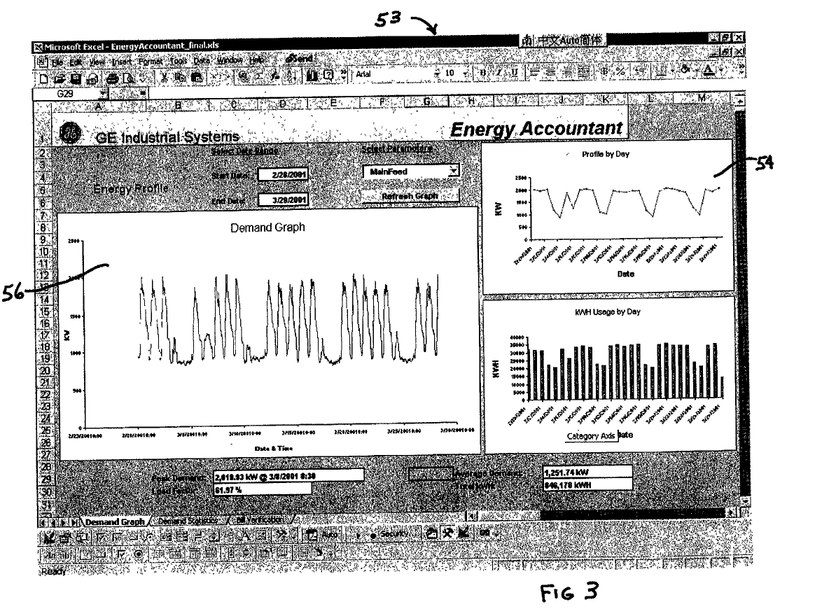

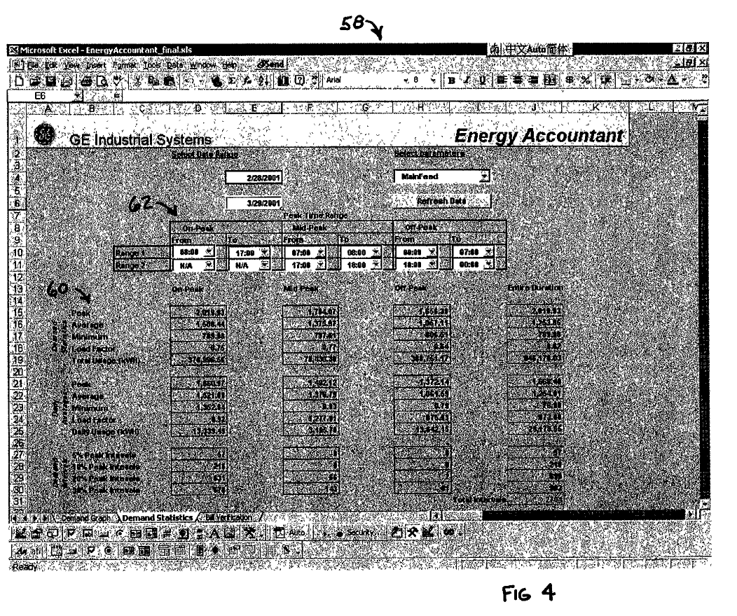

The electrical usage information is stored in a database on the server 43 for additional analysis. Upon request of the system user, the data is analyzes and various reports can be generated as shown in FIGS. 3, 4, & 5. These reports allow the user to determine how efficiently the facility is using electricity to minimize the associated costs.

Since electrical usage is not constant throughout the day or throughout the week, a demand graph report 53 is generated as is shown in FIG. 3. The demand report 53 includes a weekly demand profile 54 and a daily demand profile 56 which show which days and weeks generate the maximum demand. These reports are important to the user since the electrical utilities use an electrical usage cost profile to charge different rates depending on the day of the week, and the time of day during which the energy is used. Thus the facility can realize tremendous savings in electrical costs by timing their peak electrical usage during the time periods with the lowest rates.

FIG. 4 depicts the demand statistics report 58 which shows the electrical usage parameters 60 for various time and date ranges 62. Typical electrical parameters 60 reported include peak, average and minimum demand, daily averages and interval peaks.

The power management system also provides a bill verification report 64 which takes the electrical parameters 66 and electrical usage profile to determine the costs associated with the electrical usage of the facility during On-peak 68, Mid-peak 70 and Off-peak 72 time periods. Thus the user can determine the actual charges for a given period of time to compare and verify the electricity bill sent by the electric utility company.

In an alternate embodiment, the various report creation functionality is performed with in the meter and the report is transmitted by the communications device to the server for review by the system user. It is contemplated that the report information would be transmitted used using any proprietary or more preferably a industry standard protocol (e.g. html). As described herein above, the server could be a handheld personal digital assistant which retrieves the data directly from the communications device (e.g. radio or optically).

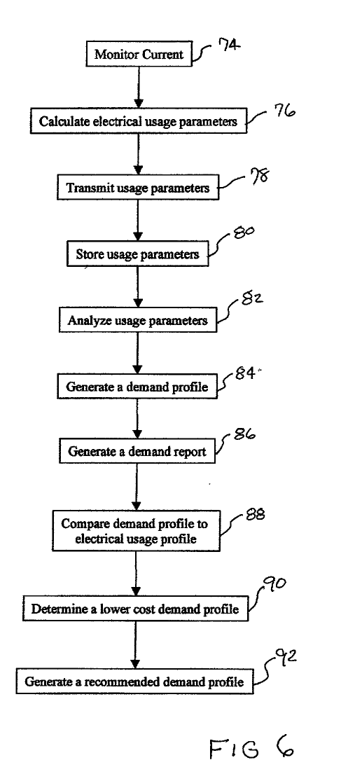

A process for minimizing electrical costs is illustrated in FIG. 6. The current is monitored 74 using a device such as a current transformer as described herein above. Electrical parameters are calculated 76 from the monitored current and transmitted 78 to a server. The server stores 80 the electrical usage parameters. The stored usage parameters are analyzed 82 to generate 84 a demand profile which is indicative of the electrical demand over the course of a desired amount of time. A report 86 of the demand profile may be generated.

To better optimize the use of electricity by the facility, the demand profile is compared 88 against the electrical usage cost profile. The two profiles are compared to determine 90 which demand peaks are associated with the higher cost periods. Once the high cost demand peaks are determined, a recommended demand profile is generated 92 to lower the electrical costs of the facility. The recommend demand profile will typically move high demand peaks into lower cost time periods, for example, turning the air conditioning off during the day, or starting process motors early in the morning.

Alternatively, the optimization process and iterative analysis which automatically adjusts the energy usage of the facility. Various subsystems could be classified as discretionary or critical with the monitoring system bringing various systems on and off line in order to minimize the cost of electricity.

While the invention has been described with reference to a preferred embodiment, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A retrofitable power monitoring system comprising:
an enclosure;
at least one current transformer within said enclosure;
a meter connected to said current transformer;
a communications device connected to said meter; and
a server connected to said communications device.

2 The retrofitable power monitoring system of claim 1 wherein said meter stores information related to electrical usage.

3. The retrofitable power monitoring system of claim 2 wherein said communications device periodically sends said electrical usage information from said meter to said server.

4. The retrofitable power monitoring system of claim 1 further comprising a software module coupled to said server.

5. The retrofitable power monitoring system of claim 4 wherein said software module includes a database object, said database including electrical usage information; an analysis object coupled to said database for analyzing said electrical usage information; and, a reporting object coupled to said database object and said analysis object.

6. The retrofitable power monitoring system of claim 5 wherein said reporting object provides a plurality of predefined or user-defined reports.

7. The retrofitable power monitoring system of claim 6 wherein said plurality of reports includes a report from a group consisting of demand graph, demand statistics, or bill verification.

8. The retrofitable power monitoring system of claim 7 further comprising a monitor connected to said server, said reporting object displaying said plurality of reports on said monitor.

9. The retrofitable power monitoring system of claim 6 further comprising a comparator object coupled to said database object, said comparator object periodically comparing said electrical usage information and a predefined electrical rate profile.

10. The retrofitable power monitoring system of claim 9 wherein said comparator object determines a maximum electrical cost period.

11. The retrofitable power monitoring system of claim 10 wherein said reporting object is coupled to said comparator object, said reporting objecting providing a report showing said maximum electrical cost period and said minimum electrical cost period.

12. The retrofitable power monitoring system of claim 11 wherein said reporting object provides an recommended electrical usage profile that reduces the cost associated with the maximum electrical cost period.

13. The retrofitable power monitoring system comprising:
a plurality of electrical usage monitoring devices, each of said plurality of monitoring devices collecting information related to electric usage in a discreet location;
a server connected to communicate with said plurality of monitoring devices;
a database object coupled to said server, said database object storing said electrical usage information received from said plurality of monitoring devices;
an analysis object coupled to said database for analyzing said electrical usage information; and,
a reporting object coupled to said database object and said analysis object.

14. The retrofitable power monitoring system of claim 13 further comprising a comparator object coupled to said database object, said comparator object periodically comparing said electrical usage information of each of said plurality of monitoring devices and an electrical rate profile.

15. The retrofitable power monitoring system of claim 14 wherein said comparator object determines a maximum electrical cost period for each of said plurality of monitoring devices.

16. The retrofitable power monitoring system of claim 15 wherein said comparator object determines a minimum electrical cost period for each of said plurality of monitoring devices.

17. The retrofitable power monitoring system of claim 16 wherein said reporting object is coupled to said comparator object, said reporting object providing a report showing said maximum electrical cost period and said minimum electrical cost period for each of said plurality of monitoring devices.

18. The retrofitable power monitoring system of claim 16 wherein said reporting object provides a recommended electrical usage profile that reduces the cost associated with the maximum electrical cost period for at least one of said plurality of monitoring devices.

19. The retrofitable power monitoring system of claim 13 wherein said reporting object provides a plurality of predefined reports.

20. The retrofitable power monitoring system of claim 19 wherein said plurality of reports includes a report from a group consisting of demand statistics, demand statistics, or bill verification.

21. The retrofitable power monitoring system of claim 19 further comprising a monitor connected to said server, said reporting object displaying said plurality of reports on said monitor.

22. A retrofitable system for monitoring electrical usage comprising:
a current sensor;
a meter coupled to said current sensor, said current sensor providing a signal to said meter indicative of said current;
a storage device associated with said meter, said meter storing electrical usage information on said storage device;
a communications device associated to said storage device;
a server coupled to said communications device, said communications device periodically transmitting said usage information to said server; and,
a means associated with said server for reporting electrical usage.

23. A retrofitable system for monitoring electrical usage as in claim 22 wherein said communications device is a wireless type.

24. A retrofitable system for monitoring electrical usage as in claim 23 wherein said communications device transmits said usage information to said server by an infrared signal.

25. A retrofitable system for monitoring electrical usage as in claim 23 wherein wherein said communications device transmits said usage information to said server by a radio signal.

26. A retrofitable system for monitoring electrical usage as in claim 23 wherein wherein said communications device transmits said usage information to said server by a cellular signal.

27. A retrofitable system for monitoring electrical usage as in claim 22 wherein said communications device transmits said usage information to said server by an Ethernet network.

28. A retrofitable system for monitoring electrical usage as in claim 22 wherein said communications device transmits said usage information to said server via a telephone line.

29. A retrofitable system for monitoring electrical usage as in claim 22 wherein said reporting means is a software module, said software module including a database object, an analysis object and a reporting object.

30. A retrofitable system for monitoring electrical usage as in claim 29 further comprising a monitor, said monitor coupled to said server.

31. A method for monitoring electrical usage comprising:
sensing an electrical current;
receiving a signal indicative of the electrical current;
calculating electrical usage information associated with said received signal;
storing the electrical usage information;
transmitting the electrical usage information to a server;
analyzing the electrical usage information; and,
reporting electrical usage parameters.

32. A method of monitoring electrical usage as in claim 31 wherein said reporting includes information on electrical demand.

33. A method of monitoring electrical usage as in claim 31 further comprising the step of comparing said electrical usage against a predetermined electrical rate profile.

34. A method of monitoring electrical usage as in claim 33 further comprising the step of creating an electrical cost profile.

35. A method of monitoring electrical usage as in claim 34 further comprising the step of analyzing the electrical cost profile.

36. A method of monitoring electrical usage as in claim 35 further comprising the step of determining a recommended electrical usage profile that minimizes the electrical cost profile.
